(19) United States
(12) Patent Application Publication
(10) Pub. No.: US 2011/0080372 A1
(43) Pub. Date: Apr. 7, 2011

(54) ORGANIC LIGHT EMITTING DISPLAY DEVICE AND MANUFACTURING METHOD THEREOF

(76) Inventors: Jaedo Lee, Gumi-si (KR); Sangwoo Seo, Daegu (KR)

(21) Appl. No.: 12/895,220

(22) Filed: Sep. 30, 2010

(30) Foreign Application Priority Data
Oct. 6, 2009 (KR) 10-2009-0094738

(51) Int. Cl. G06F 3/045; H01L 33/48

(52) U.S. Cl. 345/174; 438/27; 257/E33.056

(57) ABSTRACT

An organic light emitting display device comprises: a display panel disposed between first and second substrates and comprising subpixels; a touch screen panel disposed on a display surface of the display panel; a sensing unit for sensing a position by a change in the resistance of the touch screen panel; and a polarizing plate disposed on the touch screen panel, wherein the touch screen panel comprises first transparent electrodes formed on one surface of the second substrate, spacers formed on the first transparent electrodes, a glass substrate attached to the second substrate, and second transparent electrodes disposed on one surface of the glass substrate so as to face the first transparent electrodes.

This application claims the benefit of Korea Patent Application No. 10-2009-0094738, filed on Oct. 6, 2009, the entire contents of which is incorporated herein by reference for all purposes as if fully set forth herein.

### BACKGROUND

1. Field of the Invention

This document relates to an organic light emitting display device and a manufacturing thereof.

2. Discussion of the Related Art

An organic light emitting element used for an organic light emitting display device is a self-emittion element in which a light emitting layer is formed between two electrodes positioned on a substrate. Organic light emitting display devices are divided into a top-emission type, a bottom-emission type, and a dual-emission type according to a light emission direction. Organic light emitting display devices are divided into a passive matrix type and an active matrix type according to a driving method.

A subpixel disposed in the organic light emitting display device comprises a transistor unit including a switching transistor, a driving transistor, and a capacitor and an organic light emitting diode including a lower electrode connected to the driving transistor included in the transistor unit, an organic light emitting layer, and an upper electrode.

In the organic light emitting display device, a scan signal, a data signal, a power, etc. are supplied to a plurality of subpixels arranged in a matrix format and light is emitted from the selected subpixels, thereby displaying an image. The organic light emitting display device is advantageous in that it can be realized as a thin display device. Much research has been recently made to add a touch screen function to thin display devices such as the organic light emitting display device.

However, the conventional organic light emitting display device with a touch screen function has the problem of degradation in outdoor visibility due to reflected light because, if external light is incident into the inside, the reflectance is increased by a difference in the refractive index of a touch screen panel. Thus, improvement thereof is required.

### BRIEF SUMMARY

An organic light emitting display device comprises: a display panel disposed between first and second substrates and comprising subpixels; a touch screen panel disposed on a display surface of the display panel; a sensing unit for sensing a position by a change in the resistance of the touch screen panel; and a polarizing plate disposed on the touch screen panel, wherein the touch screen panel comprises first transparent electrodes formed on one surface of the second substrate, spacers formed on the first transparent electrodes, a glass substrate attached to the second substrate, and second transparent electrodes disposed on one surface of the glass substrate so as to face the first transparent electrodes.

In another aspect, an organic light emitting display device comprises: a display panel disposed between first and second substrates and comprising subpixels; a touch screen panel disposed on a display surface of the display panel; a sensing unit for sensing a position by a change in the resistance of the touch screen panel; and a polarizing plate disposed on the touch screen panel, wherein the touch screen panel comprises a first glass substrate disposed on the first substrate, first transparent electrodes formed on one surface of the first glass substrate, spacers formed on the first transparent electrodes, a second glass substrate attached to the first glass substrate, and second transparent electrodes disposed on one surface of the second glass substrate so as to face the first transparent electrodes.

In still another aspect a manufacturing method of an organic light emitting display device comprises: forming a transistor part on one surface of a first substrate and forming an organic light emitting diode on the transistor part; forming first transparent electrodes on one surface of a second substrate; preparing a display panel by attaching together one surface of the first substrate and the other surface of the second substrate; forming spacers on the first transparent electrodes disposed on the second substrate; forming second transparent electrodes crossing the first transparent electrodes on one surface of a glass substrate; attaching a polarizing plate to the other surface of the glass substrate; and attaching together the second substrate and the glass substrate.

In yet another aspect, a manufacturing method of an organic light emitting display device comprises: forming a transistor part on one surface of a first substrate and forming an organic light emitting diode on the transistor part; attaching a first glass substrate to one surface of a second substrate and forming first transparent electrodes on the first glass substrate; preparing a display panel by attaching together one surface of the first substrate and the other surface of the second substrate; forming spacers on the first transparent electrodes disposed on the first glass substrate; forming second transparent electrodes crossing the first transparent electrodes on one surface of a second glass substrate; attaching a polarizing plate to the other surface of the second glass substrate; and attaching together one surface of the first glass substrate and one surface of the second glass substrate.

### BRIEF DESCRIPTION OF THE DRAWINGS

The accompanying drawings, which are included to provide a further understanding of the invention and are incorporated on and constitute a part of this specification, illustrate embodiments of the invention and together with the description serve to explain the principles of the invention.

FIG. 1 is a schematic block diagram of an organic light emitting display device according to one exemplary embodiment of the present invention;

FIG. 2 is a block diagram for explaining a touch screen panel and a sensing unit shown in FIG. 1;

FIG. 3 is an illustration of the configuration of electrodes of the touch screen panel shown in FIG. 1;

FIG. 4 is a cross-sectional view of an organic light emitting display device according to a first exemplary embodiment of the present invention;

FIG. 5 is a partial cross-sectional view of a display panel shown in the “SP” area of FIG. 4;

FIG. 6 is a view showing a hierarchical structure of an organic light emitting diode;

FIG. 7 is a cross-sectional view of an organic light emitting display device according to a second exemplary embodiment of the present invention;

FIG. 8 is a cross-sectional view of an organic light emitting display device according to a comparative example;

FIG. 9 is a cross-sectional view of an organic light emitting display device according to an exemplary embodiment of the present invention;

FIGS. 10 and 11 are views for explaining the characteristics of the organic light emitting display device according to the exemplary embodiment of the present invention;

FIG. 12 is a flowchart for explaining a manufacturing method of the organic light emitting display device according to the exemplary embodiment of the present invention; and

FIG. 13 is a cross-sectional view of the organic light emitting display device manufactured by the manufacturing method of FIG. 12.

### DETAILED DESCRIPTION OF THE DRAWINGS AND THE PRESENTLY PREFERRED EMBODIMENTS

Reference will now be made in detail embodiments of the invention, examples of which are illustrated in the accompanying drawings.

Hereinafter, a concrete example according to an embodiment of the present invention will be described with reference to the attached drawings.

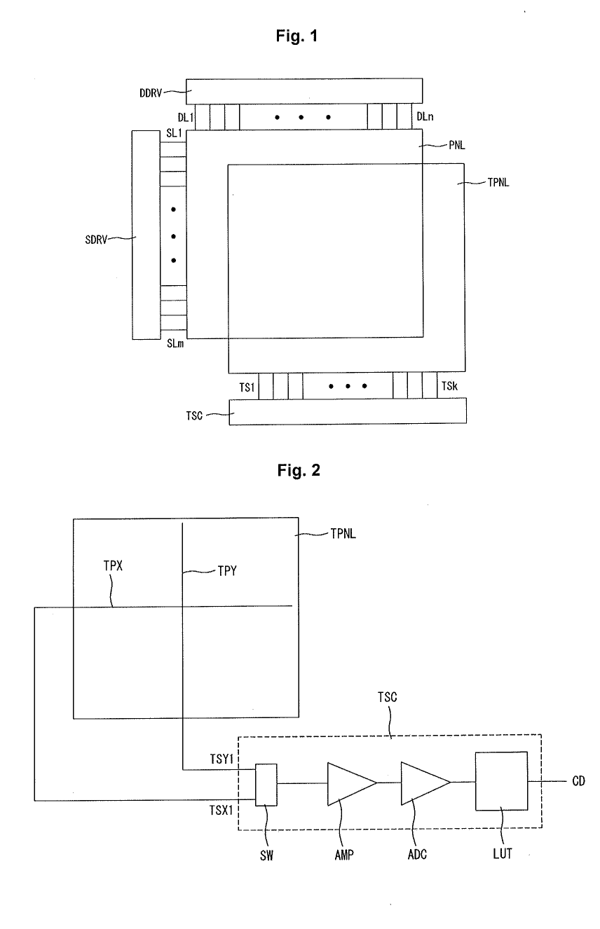

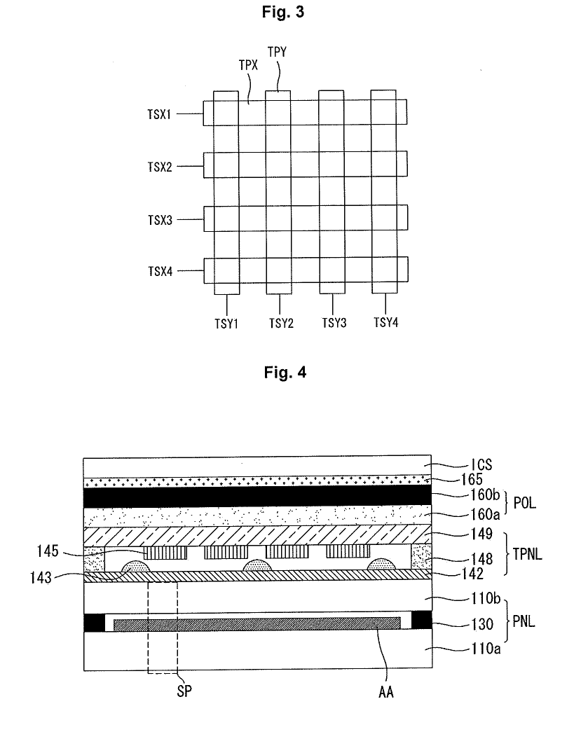

FIG. 1 is a schematic block diagram of an organic light emitting display device according to one exemplary embodiment of the present invention, FIG. 2 is a block diagram for explaining a touch screen panel and a sensing unit shown in FIG. 1, and FIG. 3 is an illustration of the configuration of electrodes of the touch screen panel shown in FIG. 1

Referring to FIGS. 1 to 3, an organic light emitting display device according to one exemplary embodiment of the present invention comprises a display panel PNL, a touch screen panel TPNL, a scan driver SDRV, a data driver DDRV, and a sensing unit TSC.

Although the display panel PNL may comprise a flat panel display FPD, such as an organic light emitting display device panel, a liquid crystal display panel, and a plasma display panel, this exemplary embodiment takes the organic light emitting display device panel as an example. The scan driver SDRV supplies scan signals to scan lines SL1 . . . SLm connected to subpixels included in the display panel PNL. The data driver DDRV supplies data signals to data lines DL1 . . . DLn connected to the subpixels included in the display panel PNL. The touch screen panel TPNL is disposed on a display surface of the display panel PNL. The sensing unit TSC senses a position touched by a user through line parts TS1 . . . TSk connected to the touch screen panel TPNL. One TS1 of the line parts TS1 . . . TSk connected to the sensing unit TSC comprises two pairs of lines to be connected to transparent electrodes TPX and TPY included in the touch screen panel TPNL in different coordinates from each other.

The sensing unit TSC is connected to the transparent electrodes TPX and TPY included in the touch screen panel TPNL through the line parts TS1 . . . TSk. When the user touches the touch screen panel TPNL, the sensing unit TSC recognizes a change in the resistance of the transparent electrodes TPX and TPY included in the touch screen panel TPNL and senses the touched position. The sensing unit TSC may comprise, for example, a signal input part SW, a signal amplifier AMP, a signal converter, and a signal detector LUT, but this invention is not limited thereto. The signal input part SW receives signals through lines TSX1 and TSY1 connected to the transparent electrodes TPX and TPY included in the touch screen panel TPNL. The signal amplifier AMP amplifies the signals received by the signal input unit SW. The signal converter ADC converts the signals input as analog signals into digital signals. The signal detector LUT detects positional data indicative of where the user has touched by recognizing a change in resistance in each coordinate, and transmits the detected positional data to a device CD where the data is used.

As explained above, the sensing unit TSC can sense a touched position by recognizing a change in the resistance of the transparent electrodes TPX and TPY included in the touch screen panel TPNL. The structure of the transparent electrodes TPX and TPY of the touch screen panel TPNL for implementing this is as follows.

The transparent electrodes TPX and TPY may comprise first transparent electrodes TPX arranged so as to be divided in an x-axis direction and second transparent electrodes TPY arranged so as to be divided in a y-axis direction. The first transparent electrodes TPX and the second transparent electrodes TPY are patterned to be positioned on different layers, and the patterned first and second transparent electrodes TPX and TPY are connected to the sensing unit TSC through the lines TSX1 and TSY1. FIG. 3 is merely illustrated to facilitate the understanding of the structure of the first and second transparent electrodes TPX and TPY, but the present invention is not limited thereto.

Now, the organic light emitting display device according to one exemplary embodiment of the present invention will be described in more details.

<First Exemplary Embodiment>

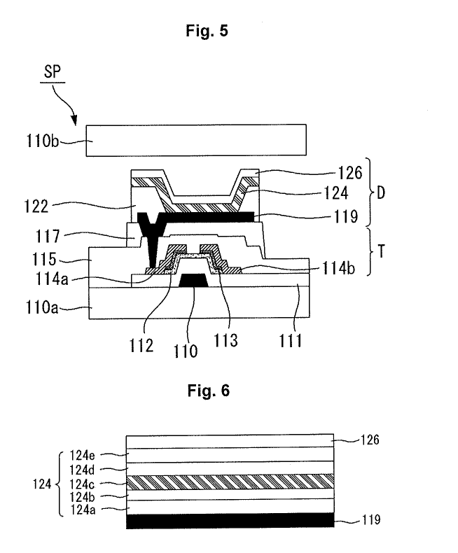

FIG. 4 is a cross-sectional view of an organic light emitting display device according to a first exemplary embodiment of the present invention, FIG. 5 is a partial cross-sectional view of a display panel shown in the “SP” area of FIG. 4, and FIG. 6 is a view showing a hierarchical structure of an organic light emitting diode.

Referring to FIGS. 4 to 6, the organic light emitting display device according to the first exemplary embodiment of the present invention comprises a display panel PNL having a display section AA, a touch screen panel TPNL disposed on an upper display surface of the display panel PNL, a polarizing plate POL disposed on the touch screen panel TPNL, and a protective sheet ICS disposed on the polarizing plate POL.

Subpixels arranged in a matrix form are formed on the display section AA of the display panel PNL. Each of the subpixels comprises a switching transistor driven by a scan signal, a capacitor storing a data signal as a data voltage, a driving transistor driven by the data voltage stored in the capacitor, and an organic light emitting diode emitting light upon driving of the driving transistor. When the scan signal and the data signal are supplied to the subpixels, the subpixels emit light and the display panel 100 displays the corresponding image. The display panel PNL may be formed as a top-emission type, a bottom-emission type, or the like. A subpixel will be described below with reference to the partial cross-sectional view of the display panel PNL.

A gate 110 is disposed on one surface of a first substrate 110a. The gate 110 The gate 112 may be made of one selected from the group consisting of molybdenum Mo, aluminum Al, chrome Cr, gold Au, titanium Ti, nickel Ni, neodymium Nd, copper Cu, and alloy thereof. The gate 110 may be a multilayer formed of one selected from the group consisting of molybdenum Mo, aluminum Al, chrome Cr, gold Au, titanium Ti, nickel Ni, neodymium Nd, copper Cu, and alloy thereof. The gate 110 may be also a dual layer of molybdenum/aluminum-neodymium or molybdenum/aluminum.

A first insulation layer 111 is disposed on the gate 110. The first insulation layer 111 may be made of a silicon oxide layer SiOx, a silicon nitride layer SiNx, or may be a multilayer thereof. However, the first insulation layer 111 is not limited thereto.

An active layer 112 is disposed on the first insulation layer 111. The active layer 112 may comprise amorphous silicon or polycrystalline silicon which is crystallized amorphous silicon. The active layer 112 may comprise a source area, a channel area, and a drain area. Also, an ohmic contact layer 113 may be disposed on the active layer 112.

A source 114a and a drain 114b to be respectively connected to the source and drain areas are disposed on the ohmic contact layer 113. The source 114a and the drain 114b may be formed as a single layer or a multilayer. If the source 114a and the drain 114b are a single layer, the source 114a and the drain 114b may be made of one selected from the group consisting of molybdenum (Mo), aluminum (Al), chrome (Cr), gold (Au), titanium (Ti), nickel (Ni), neodymium (Nd), copper (Cu), and alloy thereof. If the source 114a and the drain 114b are a multilayer, the source 114a and the drain 114b may be a dual layer of molybdenum/aluminum-neodymium or molybdenum/aluminum, or a triple layer of molybdenum/aluminum-neodyminum/molybdenum.

A second insulation layer 115 is disposed on the source 114a and the drain 114b. The second insulation layer 115 may be a silicon oxide layer SiOx, a silicon nitride layer SiNx, or a multilayer thereof. However, the second insulation layer 115 is not limited thereto.

A third insulation layer 117 is disposed on the second insulation layer 115. The third insulation layer 117 may be a silicon oxide layer SiOx, a silicon nitride layer SiNx, or a multilayer thereof. However, the third insulation layer 117 is not limited thereto.

A lower electrode 119 connected to the source 114a or the drain 114b is disposed on the third insulation layer 117. The lower electrode 119 may be selected as a cathode or anode. If the lower electrode 119 is selected as a cathode, the cathode may be formed of one of aluminum, an aluminum alloy, and aluminum-neodymium AINd. However, the lower electrode 119 is not limited thereto. If the lower electrode 119 is selected as a cathode, the cathode may be advantageously formed of a highly reflective material.

A bank layer 122 having an opening for exposing a part of the lower electrode 119 is formed on the lower electrode 119. The bank layer 122 may comprise organic material such as benzocyclobutene (BCB) resin, acrylic resin, or polyimide resin. However, the bank layer 122 is not limited thereto.

An organic light emitting layer 124 is disposed on the lower electrode 119. As shown in FIG. 6, the organic light emitting layer 124 may comprise an electron injection layer 124a, an electron transport layer 124b, an emission layer 124c, a hole transport layer 124d, and a hole injection layer 124e.

The electron injection layer 124a makes the injection of electron smooth and may be made of tris(8-hydroxyquinolino)aluminum (Alq3), PBD, TAZ, spiro-PBD, BAlq, LiF, or SAlq. However, the electron injection layer 124a is not limited thereto. The electron transport layer 124b makes the transport of electrons smooth and may be made of one or more selected from the group consisting of Alq3(tris(8-hydroxyquinolino)aluminum), PBD, TAZ, spiro-PBD, BAlq, LiF, or SAlq. However, the electron transport layer 124b is not limited thereto. The emission layer 124c may comprise material that emits red, green, or blue light. Also, the emission layer 124c may be made of phosphorescent or fluorescent material. If the emission layer 124c emits red light, the emission layer 124c may be made of phosphorescent material including a host having carbazole biphenyl (CBP) or 1,3-bis(carbazol-9-yl) mCP and a dopant having at least one selected from the group consisting of PIQr(acac)(bis(1-phenylisoquinoline)acetylacetonate iridium), PQIr(acac)(bis(1-phenylquinoline)acetylacetonate iridium), PQIr(tris(1-phenylquinoline)iridium), and PtOEP(octaethylporphyrin platinum). Also, the emission layer 124c may be made of fluorescent material having PBD:Eu(DBM)3(Phen) or Perylene. However, the emission layer 124c is not limited thereto. If the emission layer 124c emits green light, the emission layer 124c may be made of phosphorescent material including a host having CBP or mCP and a dopant having Ir(ppy)3(fac tris(2-phenylpyridine)iridium). Alternatively, the emission layer 124c may be made of a fluorescent material having Alq3(tris(8-hydroxyquinolino)aluminum). However, the emission layer 124c is not limited thereto. If the emission layer 124c emits blue light, the emission layer 124c may be made of phosphorescent material including a host having CBP or mCP and a dopant having (4,6-F2ppy)2Irpic. Alternatively, the emission layer 124c may be made of fluorescent material having one selected from the group consisting of spiro-DPVBi, spiro-6P, distryrylbenzene (DSB), distyryl arylene (DSA), PFO polymer, and PPV polymer. However, the emission layer 124c is not limited thereto. The hole transport layer 124d makes the transport of holes smooth. The hole transport layer 124d may be made of one selected from the group consisting of NPD(N,N-dinaphthyl-N,N′-diphenyl benzidine), TPD(N,N′-bis-(3-methylphenyl)-N,N′-bis-(phenyl)-benzidine), s-TAD, and MTDATA(4,4′,4″-Tris(N-3-methylphenyl-N-phenyl-amino)-triphenylamine). However, the hole transport layer 124d is not limited thereto. The hole injection layer 124e makes the injection of holes smooth. The hole injection layer 124e may be made of one selected from the group consisting of CuPc(cupper phthalocyanine), PEDOT(poly(3,4)-ethylenedioxythiophene), PANI(polyaniline), and NPD(N,N-dinaphthyl-N,N′-diphenyl benzidine). However, the hole injection layer 124e is not limited thereto. Here, the present invention is not limited to FIG. 6, and at least one of the electron injection layer 124a, the electron transport layer 124b, the hole transport layer 124d, and the hole injection layer 124e may be omitted.

An upper electrode 126 is disposed on the organic light emitting layer 124. The upper electrode 126 may be selected as an anode or cathode. Here, the upper electrode 126 selected as the anode may be formed of one of Indium Tin Oxide (ITO), Indium Zinc Oxide (IZO), Indium Tin Zinc Oxide (ITZO), and ZnO doped Al203. However, the upper electrode 126 is not limited thereto.

With this structure, subpixels, each comprising a transistor part T including a switching transistor, a driving transistor, a capacitor, etc and an organic light emitting diode D, are disposed in matrix on one surface of the first substrate 110a. The subpixels formed on one surface of the first substrate 110a display an image in the direction of a second substrate 110b. That is, the display panel PNL is configured as a top-emission type.

The subpixels disposed on one surface of the first substrate 110a are weak to moisture or oxygen. Therefore, the first substrate 110a and the second substrate 110b may be attached and sealed by an adhesive member 130, e.g., frit glass or a sealant.

The touch screen panel 140 comprises first transparent electrodes 142 formed on one surface of the second substrate 110b constituting the display panel PNL, spacers 143 formed on the first transparent electrodes 142, a glass substrate 149 attached to the second substrate 110b, and second transparent electrodes 145 formed on one surface of the glass substrate 149 so as to face the first transparent electrodes 142. The second substrate 110b and the glass substrate 149 are attached together by an adhesive portion 148, such as a double-side tape or adhesive. The first transparent electrodes 142 and the second transparent electrodes 145 are patterned to be divided into a plurality of parts so as to cross each other as shown in FIG. 3, and they are connected to the sensing unit TSC through different lines TSX1 and TXY1 as shown in FIG. 2. Here, the spacers 143 are structures for maintaining a gap between the glass substrate 149 and the second substrate 110b, and the configuration thereof is not limited thereto.

The polarizing plate POL comprises a phase difference delay film 160a disposed on the touch screen panel 140 and a polarizing film 160b disposed on the phase difference delay film 160a. The phase difference delay film 160a may have an optical axis having a phase difference of λ/4 with respect to incident light, and the polarizing film 160b may have an absorption axis for polarizing unpolarized light.

The protective sheet ICS is attached onto the polarizing plate POL by an adhesive 165, e.g., an optical clear adhesive (OCA). The protective sheet ICS may be printed with a specific figure, such as an icon, or formed in plain form, and it is attached for various purposes such as protecting the polarizing plate POL.

<Second Exemplary Embodiment>

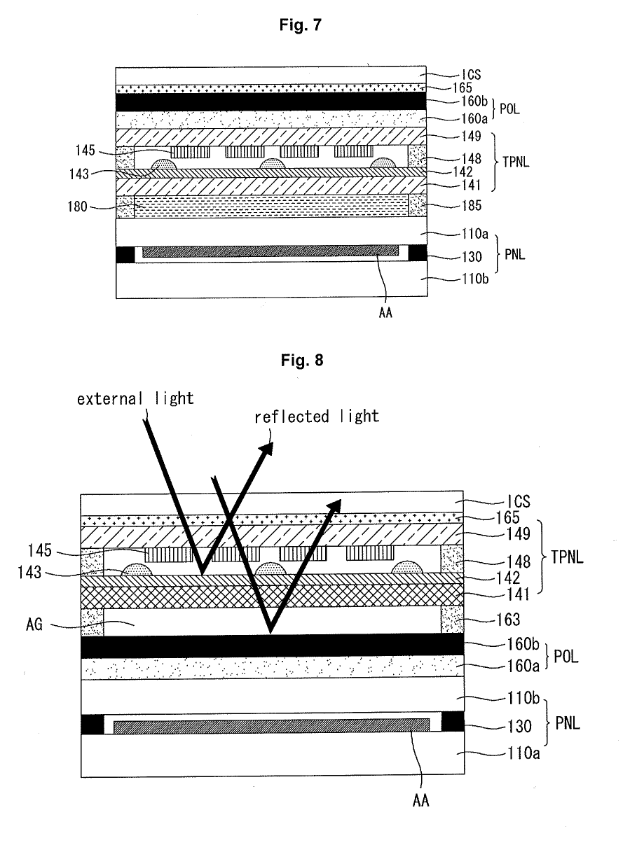

FIG. 7 is a cross-sectional view of an organic light emitting display device according to a second exemplary embodiment of the present invention.

Referring to FIG. 7, the organic light emitting display device according to the second exemplary embodiment of the present invention comprises a display panel PNL having a display section AA, a touch screen panel TPNL disposed on a lower display surface of the display panel PNL, a polarizing plate POL disposed on the touch screen panel TPNL, and a protective sheet ICS disposed on the polarizing plate POL.

Unlike the first exemplary embodiment, the organic light emitting display device according to the second exemplary embodiment of the present invention displays an image in the direction of the first substrate 110a. That is, the display panel PNL is configured as a bottom-emission type. Also, the subpixels disposed on one surface of the first substrate 110a are weak to moisture or oxygen. Therefore, as in the first exemplary embodiment, the first substrate 110a and the second substrate 110b are attached and sealed by an adhesive member 130, e.g., frit glass or a sealant.

The touch screen panel TPNL is attached to the first substrate 110a constituting the display panel TPNL by an optical adhesive 180 and a double-side tape 185. However, the touch screen panel TPNL may be attached to the first substrate 110a constituting the display panel PNL by either one or both of the double-side tape 185 and the optical adhesive 180. The touch screen panel TPNL comprises a first glass substrate 141 disposed on the first substrate 110a constituting the display panel PNL, first transparent electrodes 142 formed on one surface of the first glass substrate 141, spacers 143 formed on the first transparent electrodes 142, a second glass substrate 149 attached to the first glass substrate 141, and second transparent electrodes 145 formed on one surface of the second glass substrate 149 so as to face the first transparent electrodes 142. The first transparent electrodes 142 and the second transparent electrodes 145 are patterned to be divided into a plurality of parts so as to cross each other as shown in FIG. 3, and they are connected to the sensing unit TSC through different lines TSX1 and TXY1 as shown in FIG. 2. Here, the spacers 143 are structures for maintaining a gap between the glass substrate 149 and the second substrate 110b, and the configuration thereof is not limited thereto.

The polarizing plate POL comprises a phase difference delay film 160a disposed on the touch screen panel 140 and a polarizing film 160b disposed on the phase difference delay film 160a. The phase difference delay film 160a may have an optical axis having a phase difference of λ/4 with respect to incident light, and the polarizing film 160b may have an absorption axis for polarizing unpolarized light.

The protective sheet ICS is attached onto the polarizing plate POL by an adhesive 165, e.g., an optical clear adhesive (OCA). The protective sheet ICS may be printed with a specific figure, such as an icon, or formed in plain form, and it is attached for various purposes such as protecting the polarizing plate POL.

Now, the characteristics of the organic light emitting display device according to the present invention will be described with reference to one of the foregoing exemplary embodiments and a comparative example.

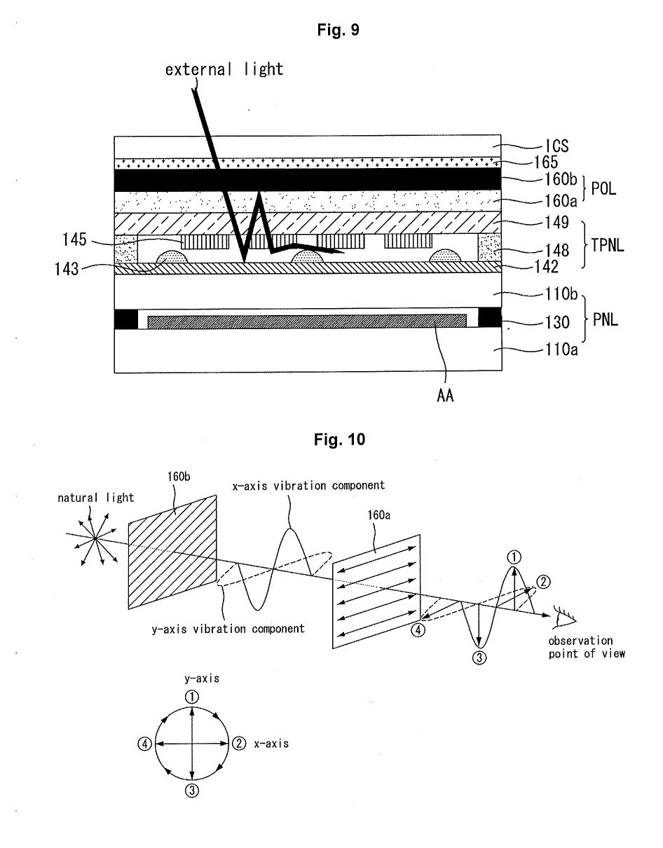

FIG. 8 is a cross-sectional view of an organic light emitting display device according to a comparative example, FIG. 9 is a cross-sectional view of an organic light emitting display device according to an exemplary embodiment of the present invention, and FIGS. 10 and 11 are views for explaining the characteristics of the organic light emitting display device according to the exemplary embodiment of the present invention

Referring to FIGS. 8 and 9, organic light emitting display devices according to the comparative example and the exemplary embodiment each comprise a display panel PNL, a touch screen panel TPNL, a polarizing plate POL, and a cover window ICS.

Referring to FIG. 8, the organic light emitting display device of the comparative example is formed in the following structure.

The polarizing plate POL is attached to the upper display surface of the display panel PNL. The touch screen panel TPNL is attached onto the polarizing plate POL by an adhesive 163 formed on outer edges of the polarizing plate POL, with an air layer AG provided therebetween. The protective sheet ICS is attached onto the touch screen panel TPNL by an optical adhesive 165 formed on the entire surface of the touch screen panel TPNL. The touch screen panel TPNL comprises first transparent electrodes 142 that are formed between a first film 141 and a second film 149 formed of polyethylene terephthalate (PET) and spacers 143 and second transparent electrodes 145 that are formed on the first transparent electrodes 142.

Referring to FIG. 9, the organic light emitting display device of the exemplary embodiment is formed in the following structure.

The touch screen panel TPNL is formed on the upper display surface of the display panel PNL. The touch screen panel TPNL comprises first transparent electrodes 142 that are formed between the second substrate 110b constituting the display panel PNL and the glass substrate 149 and spacers 143 and second transparent electrodes 145 that are formed on the first transparent electrodes. The polarizing plate POL is attached onto the touch screen panel TPNL. The protective sheet ICS is attached onto the polarizing plate POL by an optical adhesive 165 formed on the entire surface of the polarizing plate POL.

The following results were obtained after external light is shone on the comparative example and the exemplary embodiment having the above-described structures.

First, in the comparative example of FIG. 8, when external light was incident into the touch screen panel TPNL through the protective sheet ICS and the second film 149, it was seen that the frequency, i.e., reflectance, of light reflected back by the first film 141 or the first transparent electrodes 142 formed on the first film 141 was high. This result was obtained because, in the structure of the comparative example, the substrates such as the first film 141 and the second film 149 constituting the touch screen panel TPNL are formed of material such as a PET film. The PET film has light scattering characteristics, and there is a difference in the refractive index for incoming or outgoing light, thereby making the frequency of reflected light high. Moreover, in the comparative example, even when external light enters the space, i.e., air layer, between the touch screen panel TPNL and the polarizing plate POL through the touch screen panel TPNL, there exists reflected light resulting from the reflection of the external light back through the surface of the polarizing plate POL.

On the contrary, in the exemplary embodiment of FIG. 9, when external light was incident into the touch screen panel TPNL through the protective sheet ICS and the second film 149, even if the incident light was reflected back by the first transparent electrodes 142, etc, the light is reflected again by the polarizing plate POL and absorbed therein. Thus, the frequency of reflected light was very rare. This result was obtained because, in the structure of the exemplary embodiment, the substrates constituting the touch screen panel TPNL are formed of glass. The glass has little light scattering characteristics, and there is no such difference in refractive index as that in the glass, thereby making the frequency of reflected light high. Moreover, in the exemplary embodiment, even if re-reflection is caused by the first and second transparent electrodes 142 and 145 formed inside the touch screen panel TPNL, the reflected light is not reflected back because most of the reflected light is absorbed and lost by the polarizing plate POL. That is, the exemplary embodiment solved the problem as shown in the comparative example by forming the touch screen panel TPNL of a glass substrate and attaching the polarizing plate POL on the touch screen panel TPNL. Hereinafter, a description of the light transmission characteristics of the polarizing plate POL will be added to facilitate the understanding of the structure of the exemplary embodiment.

Referring to FIG. 10, when unpolarized external light (or natural light) is incident, the polarizing plate POL polarizes the light into an x-axis vibration component and a y-axis vibration component along the absorption axis of the polarizing film 160b. Afterwards, of the light polarized into the respective vibration components, the x-axis vibration component becomes slower than the y-axis vibration component by λ/4. When viewed from the observation point, the light incident through the phase difference delay film 160a has the characteristic that it vibrates in the directions of \textcircled{1}, \textcircled{2}, \textcircled{3}, and \textcircled{4}.

Referring to FIG. 11, in the exemplary embodiment, the polarizing plate POL is disposed on top of the touch screen panel TPNL by using the aforementioned characteristic of the polarizing plate POL. Thus, in the structure of the exemplary embodiment, when external light (or natural light) is incident, the incident light is polarized in the “IP” direction by the phase difference delay film 160a of the polarizing plate POL and becomes slower by λ/4. The light reflected by the first and second transparent electrodes 142 and 145 disposed below the polarizing plate POL is polarized in the “OP” direction and becomes slower by λ/4 as it passes again through the phase difference delay film 160a of the polarizing plate POL. At this time, the reflected light is polarized in the “OP” direction but is not transmitted through a “crossed nicole (ON)” formed on the absorption axis of the polarizing film 160b. That is, the natural light (or external light) incident through the polarizing plate POL is reflected and brought back as if it passed through a plate of λ/4+80 /4=λ/2. Since the λ/2 plate changes a polarization state to 90 degrees, the external light (or natural light) incident through the polarizing plate POL is not transmitted through the “ON” formed on the absorption axis of the polarizing film 160b but almost the entire amount thereof is lost.

Accordingly, the exemplary embodiment can improve degradation in outdoor visibility caused by reflected light by a reduction of the reflectance of the external light by changing the material of the substrates constituting the touch screen panel TPNL to glass and attaching the polarizing plate POL onto the touch screen panel TPNL.

<Manufacturing Method>

Now, a method for manufacturing the organic light emitting display device of the foregoing exemplary embodiments as a module will be described.

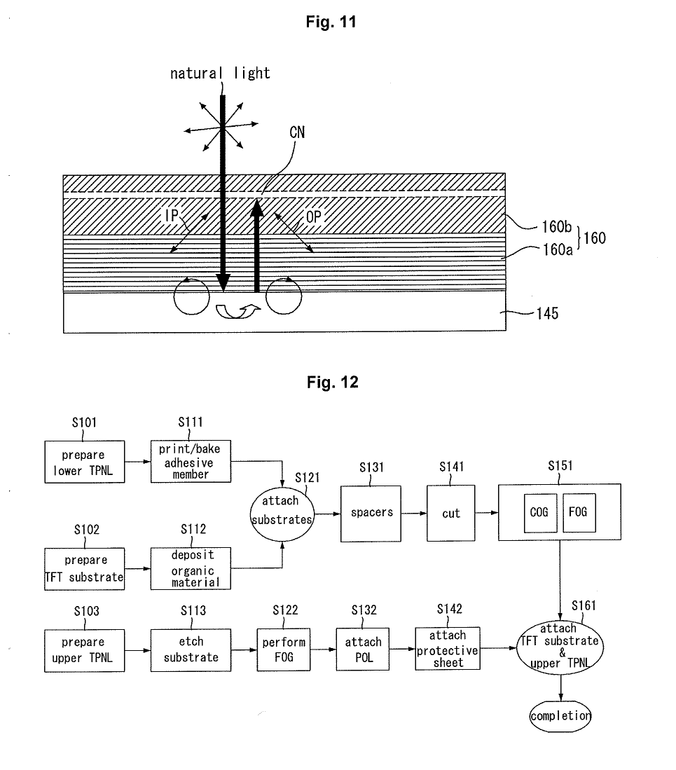

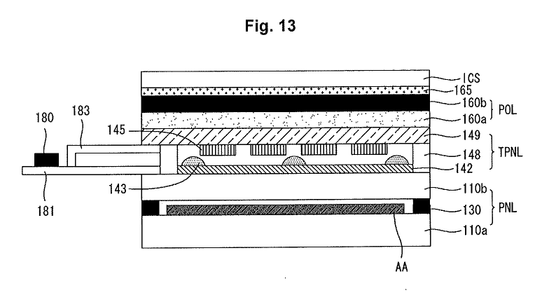

FIG. 12 is a flowchart for explaining a manufacturing method of the organic light emitting display device according to the exemplary embodiment of the present invention, and FIG. 13 is a cross-sectional view of the organic light emitting display device manufactured by the manufacturing method of FIG. 12.

As shown in FIGS. 12 and 13, in the manufacturing method of the organic light emitting display device according to one exemplary embodiment of the present invention, a process of preparing a lower TPNL, a process of preparing a TFT substrate, and a process of preparing an upper TPNL may be carried out along the same flow. However, for convenience of description, the present invention will be described in the order of lower TPNL preparation, TFT substrate preparation, and upper TPNL preparation.

A lower TPNL is prepared (S101). The lower TPNL is a lower portion of a touch screen panel TPNL, and becomes a second substrate 110b constituting a display panel PNL. According to the exemplary embodiment, first transparent electrodes 142 divided by an X-axis or a Y-axis are formed on one surface of the second substrate 110b. An adhesive member 130 is printed or baked (S111). The adhesive member 130 is formed on the other surface of the second substrate 110b opposed to the surface where the first transparent electrodes 142 are formed. In the exemplary embodiment, frit glass or a sealant is selected as the adhesive member 130.

A TFT substrate is prepared (S102). The TFT substrate is a lower portion of the display panel PNL, which corresponds to a first substrate 110a. According to the exemplary embodiment, a transistor part T including a switching transistor, a driving transistor, a capacitor, etc and an organic light emitting diode D is formed on one surface of the first substrate 110a. A lower electrode 119 is formed on the first substrate 110a where the transistor part T is formed, and a bank layer 122 exposing a part of the lower electrode 119 is formed on the lower electrode 119. An organic material is deposited (S112). According to the exemplary embodiment, an organic light emitting layer 124 is formed on the lower electrode 119. An upper electrode 126 is formed on the first substrate 110a where the organic light emitting layer 124 is formed. According to the exemplary embodiment, an organic light emitting diode D is formed on the first substrate 110a corresponding to the TFT substrate. A description of which will be made with reference to FIG. 5.

The substrates are attached together (S121). The other surface of the second substrate 110b corresponding the lower TPNL and one surface of the first substrate 110a corresponding to the TFT substrate are attached together. According to the exemplary embodiment, as the first substrate 110a and the second substrate 110b are attached together, the display panel PNL where the first transparent electrodes 141 of the touch screen panel TPNL are formed is prepared on the second substrate 110b. Spacers are formed (S131). According to the exemplary embodiment, the spacers 143 are formed on the first transparent electrodes 142 disposed on top of the second substrate 110b constituting the display panel PNL. A cutting process is performed (S141). The display panel PNL formed by the attaching process is formed on a mothersubstrate, so the attaching process is performed to divide the display panel PNL into individual cells. Chip on glass (COG)/film on glass (FOG) processes are performed. According to the exemplary embodiment, a first flexible film 181 having a sensing unit 180 mounted thereon for driving the touch screen panel TPNL is formed on one surface of the second substrate 110b, and a flexible circuit board having a drive chip for driving subpixels formed on the display section AA is attached to one surface of the first substrate 110a.

An upper TPNL is prepared (S103). The upper TPNL is an upper portion of the touch screen panel TPNL, and a glass substrate 149 is selected as the upper TPNL. Second transparent electrodes 145 divided by an X-axis or a Y-axis are formed on one surface of the glass substrate 149. The substrate is etched (S113). According to the exemplary embodiment, the other surface of the glass substrate 149 selected as the substrate is etched to have a thickness of approximately 0.1 to 0.2 mm. A FOG process is performed on the upper TPNL (S122). According to the exemplary embodiment, a second flexible film 183 is attached to one surface of the glass substrate 149. A polarizing plate POL is attached (S132). According to the exemplary embodiment, the polarizing plate POL is attached to the other surface of the glass substrate 149. A protective sheet is attached (S142). According to the exemplary embodiment of the present invention, the protective sheet ICS is attached onto the polarizing plate POL by an adhesive 165, e.g., an optical clear adhesive (OCA) or the like.

The TFT substrate and the upper TPNL are attached together (S161). According to the exemplary embodiment, as the substrates prepared as the lower TPNL and the upper TPNL, respectively, are attached together by an adhesive portion 148, such as a double-side tape or an adhesive, on the display panel PNL, an organic light emitting display device having the touch screen panel TPN formed integrally with the display panel PNL can be manufactured as a module.

The above description has been made in relation to the method for manufacturing the organic light emitting display device shown in FIG. 4 as a module. On the other hand, in the structure shown in FIG. 7, during manufacture of the touch screen panel TPNL, the first glass substrate 141 is attached to one surface of the second substrate 110b and the first transparent electrodes 142 are formed on the first glass substrate 141. Then, the second transparent electrodes 145 crossing the first transparent electrodes 142 are formed on one surface of the second glass substrate 149, and one surface of the first glass substrate 141 and one surface of the second glass substrate 149 are attached together. That is, the method for manufacturing the organic light emitting display device shown in FIG. 7 as a module, too, is performed in a similar process to that of the manufacturing method of FIGS. 12 and 13, but is different in that two glass substrates 141 and 149 are used.

As described above, the present invention provides an organic light emitting display device which can prevent the problem of an increase in reflectance due to a change in the refractive index of a touch screen panel caused by external light and improve outdoor visibility in the manufacture of the organic light emitting display device having a touch screen function. Moreover, the present invention provides an organic light emitting display device which allows a top emission type or bottom-emission type display panel and a touch screen panel to be formed in an integral form.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures. Moreover, unless the term “means” is explicitly recited in a limitation of the claims, such limitation is not intended to be interpreted under 35 USC 112(6).

1. An organic light emitting display device comprising:
a display panel disposed between first and second substrates and comprising subpixels;
a touch screen panel disposed on a display surface of the display panel;
a sensing unit that senses a position by a change in the resistance of the touch screen panel; and
a polarizing plate disposed on the touch screen panel,
wherein the touch screen panel comprises first transparent electrodes on one surface of the second substrate, spacers on the first transparent electrodes, a glass substrate attached to the second substrate, and second transparent electrodes disposed on one surface of the glass substrate so as to face the first transparent electrodes.

2. The organic light emitting display device of claim 1, wherein the polarizing plate comprises:
a phase difference delay film disposed on the touch screen panel; and
a polarizing film disposed on the phase difference delay film.

3. The organic light emitting display device of claim 2, wherein the phase difference delay film has an optical axis having a phase difference of λ/4 with respect to incident light.

4. The organic light emitting display device of claim 1, wherein the first transparent electrodes and the second transparent electrodes are patterned to be divided into a plurality of parts so as to cross each other, and the first transparent electrodes and the second transparent electrodes are connected to the sensing unit through different lines.

5. An organic light emitting display device comprising:
a display panel disposed between first and second substrates and comprising subpixels;
a touch screen panel disposed on a display surface of the display panel;
a sensing unit that senses a position by a change in the resistance of the touch screen panel; and
a polarizing plate disposed on the touch screen panel,
wherein the touch screen panel comprises a first glass substrate disposed on the first substrate, first transparent electrodes on one surface of the first glass substrate, spacers on the first transparent electrodes, a second glass substrate attached to the first glass substrate, and second transparent electrodes disposed on one surface of the second glass substrate so as to face the first transparent electrodes.

6. The organic light emitting display device of claim 5, wherein the polarizing plate comprises:
a phase difference delay film disposed on the touch screen panel; and
a polarizing film disposed on the phase difference delay film.

7. The organic light emitting display device of claim 6, wherein the phase difference delay film has an optical axis having a phase difference of λ/4 with respect to incident light.

8. The organic light emitting display device of claim 5, wherein the first transparent electrodes and the second transparent electrodes are patterned to be divided into a plurality of parts so as to cross each other, and the first transparent electrodes and the second transparent electrodes are connected to the sensing unit through different lines.

9. The organic light emitting display device of claim 5, wherein the touch screen panel is attached to the first substrate of the display panel by at least one of a double-side tape and an optical adhesive.

10. A manufacturing method of an organic light emitting display device comprising:
forming a transistor part on one surface of a first substrate and forming an organic light emitting diode on the transistor part;
forming first transparent electrodes on one surface of a second substrate;
preparing a display panel by attaching together one surface of the first substrate and the other surface of the second substrate;
forming spacers on the first transparent electrodes disposed on the second substrate;
forming second transparent electrodes crossing the first transparent electrodes on one surface of a glass substrate;
attaching a polarizing plate to the other surface of the glass substrate; and
attaching together the second substrate and the glass substrate.

11. The method of claim 10, wherein the polarizing plate comprises:
a phase difference delay film disposed on the touch screen panel; and
a polarizing film disposed on the phase difference delay film.

12. The method of claim 11, wherein the phase difference delay film has an optical axis having a phase difference of λ/4 with respect to incident light.

13. The method of claim 10, wherein the first transparent electrodes and the second transparent electrodes are patterned to be divided into a plurality of parts so as to cross each other, and the first transparent electrodes and the second transparent electrodes are connected to the sensing unit through different lines.

14. A manufacturing method of an organic light emitting display device comprising:
forming a transistor part on one surface of a first substrate and forming an organic light emitting diode on the transistor part;
attaching a first glass substrate to one surface of a second substrate and forming first transparent electrodes on the first glass substrate;
preparing a display panel by attaching together one surface of the first substrate and the other surface of the second substrate;
forming spacers on the first transparent electrodes disposed on the first glass substrate;
forming second transparent electrodes crossing the first transparent electrodes on one surface of a second glass substrate;
attaching a polarizing plate to the other surface of the second glass substrate; and
attaching together one surface of the first glass substrate and one surface of the second glass substrate.

15. The method of claim 14, wherein the polarizing plate comprises:
a phase difference delay film disposed on the touch screen panel; and
a polarizing film disposed on the phase difference delay film.

16. The method of claim 15, wherein the phase difference delay film has an optical axis having a phase difference of λ/4 with respect to incident light.

17. The method of claim 14, wherein the first glass substrate is attached to one surface of the second substrate by at least one of a double-side tape and an optical adhesive.

18. The method of claim 14, wherein the first transparent electrodes and the second transparent electrodes are patterned to be divided into a plurality of parts so as to cross each other, and the first transparent electrodes and the second transparent electrodes are connected to the sensing unit through different lines.
